(19) United States
(12) Patent Application Publication
(10) Pub. No.: US 2012/0098124 A1
(43) Pub. Date: Apr. 26, 2012

(54) SEMICONDUCTOR DEVICE HAVING UNDER-BUMP METALLIZATION (UBM) STRUCTURE AND METHOD OF FORMING THE SAME

(75) Inventors: Yi-Wen WU, Xizhi City (TW); Hung-Jui KUO, Hsinchu City (TW); Chien Ling HWANG, Hsinchu (TW); Chung-Shi LIU, Shin-Chu (TW)

(73) Assignee: TAIWAN SEMICONDUCTOR MANUFACTURING COMPANY, LTD., Hsinchu (TW)

(21) Appl. No.: 13/033,780

(22) Filed: Feb. 24, 2011

Related U.S. Application Data
(60) Provisional application No. 61/405,412, filed on Oct. 21, 2010.

(51) Int. Cl. H01L 23/498; H01L 21/28

(52) U.S. Cl. 257/737; 438/614; 257/E23.068; 257/E21.158

(57) ABSTRACT

A semiconductor device has a UBM (under-bump metallization) structure underlying and electrically connected to a solder bump. The UBM structure has a first metallization layer with a first cross-sectional dimension d₁, a second metallization layer with a second cross-sectional dimension d₂ formed on the first metallization layer, and a third metallization layer with a third cross-sectional dimension d₃ formed on the second metallization layer, in which d₁ is greater than d₃, and d₃ is greater than d₂.

### CROSS-REFERENCE TO RELATED APPLICATIONS

The present application claims priority of U.S. Provisional Patent Application Ser. No. 61/405,412, filed on Oct. 21, 2010, which is incorporated herein by reference in its entirety.

### TECHNICAL FIELD

This disclosure relates to the fabrication of semiconductor devices, and more particularly, to the fabrication of under-bump metallization (UBM) in semiconductor devices.

### BACKGROUND

Modern integrated circuits are made up of literally millions of active and/or passive devices such as transistors and capacitors. These devices are initially isolated from each other, but are later interconnected together to form functional circuits. Typical interconnect structures include lateral interconnections, such as metal lines (wirings), and vertical interconnections, such as vias and contacts. Interconnections are increasingly determining the limits of performance and the density of modern integrated circuits. On top of the interconnect structures, bond pads are formed and exposed on the surface of the respective chip. Electrical connections are made through bond pads to connect the chip to a package substrate or another die. Bond pads can be used for wire bonding or flip-chip bonding. In a typical bumping process, interconnect structures are formed on metallization layers, followed by the formation of under-bump metallization (UBM) and solder balls. Flip-chip packaging utilizes bumps to establish electrical contact between a chip's Input/Output (I/O) pads and the substrate or lead frame of the package.

Structurally, a bump refers to both the bump itself and the UBM located between the bump and an I/O pad. An UBM generally contains an adhesion layer, a barrier layer and a wetting layer, arranged in that order, on the I/O pad. The bumps themselves, based on the material used, are classified as solder bumps, gold bumps, copper pillar bumps and bumps with mixed metals. Usually, a material used for the solder bump is so-called Sn—Pb eutectic solder. Recently the semiconductor industry has been moving to “lead (Pb) free” packaging and lead-free device connector technology. To carry out the etching of the UBM, a wet etching or a dry etching is used. Wet etching has certain drawbacks in that the UBM under the solder bump is oftentimes undercut because of isotropic etching properties, and the lower layer of the UBM is more severely undercut. It usually causes low dielectric constant (low-k) dielectric delaminating issues. For these reasons, dry etching is used to mitigate the undercut issue, but it is easy to damage the bump and generate polymer residues which needs be removed by an extra process.

### BRIEF DESCRIPTION OF THE DRAWINGS

FIG. 1 is a flowchart of a method of fabricating a UBM structure in a semiconductor device according to various aspects of the present disclosure;

FIGS. 2A˜2G are cross-sectional views of a portion of a semiconductor device at various stages of its fabrication according to the method of FIG. 1;

FIG. 3 is a flowchart of another example method of fabricating a UBM structure in a semiconductor device according to various aspects of the present disclosure; and

FIGS. 4A˜4D are cross-sectional views of a portion of a semiconductor device at various stages of its fabrication according to the method of FIG. 3.

### DETAILED DESCRIPTION

This disclosure provides UBM formation processes used in semiconductor devices applied to flip-chip assembly, wafer-level chip scale package (WLCSP), three-dimensional integrated circuit (3D-IC) stack, and/or any advanced package technology fields. Embodiments described herein relate to methods of forming solder bumps on UBM structures for use with semiconductor devices. Reference will now be made in detail to exemplary embodiments illustrated in the accompanying drawings. Wherever possible, the same reference numbers are used in the drawings and the description to refer to the same or like parts. In the drawings, the shape and thickness may be exaggerated for clarity and convenience.

This description will be directed in particular to elements forming part of, or cooperating more directly with, apparatus in accordance with the present disclosure. It is to be understood that elements not specifically shown or described may take various forms well known to those skilled in the art. Further, when a layer is referred to as being on another layer or “on” a substrate, it may be directly on the other layer or on the substrate, or intervening layers may also be present. Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

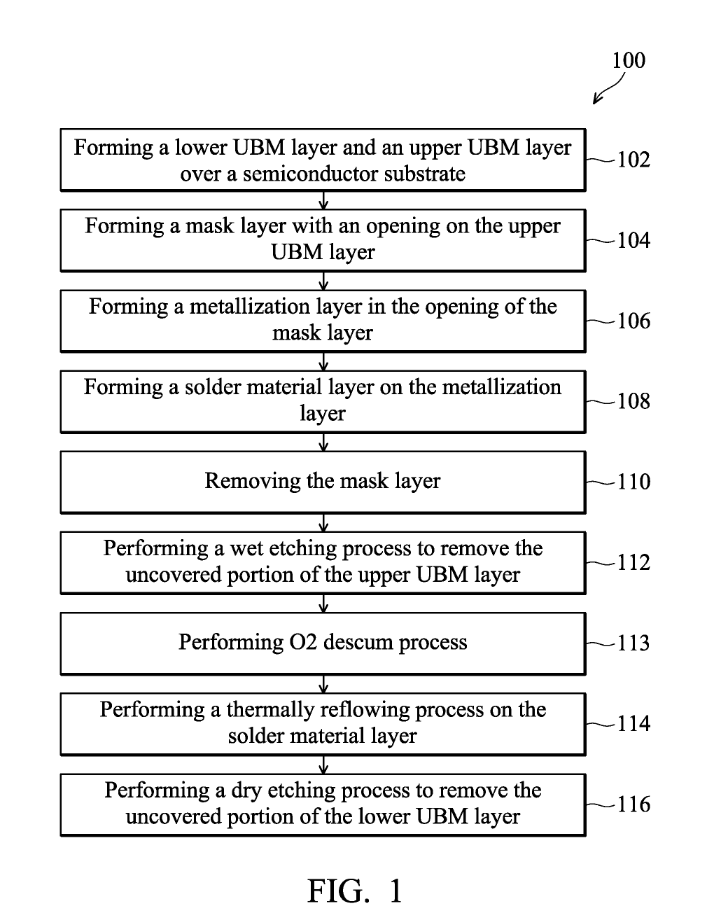

FIG. 1 is a flowchart of a method of fabricating a semiconductor device with a UBM structure according to various aspects of the present disclosure.

Referring to FIG. 1, the method 100 begins with block 102 in which a lower UBM layer and an upper UBM layer are formed over a semiconductor substrate. The method 100 continues with block 104 in which a mask layer with an opening is formed on the upper UBM layer. The method 100 continues with block 106 in which a metallization layer is formed in the opening of the mask layer. The method 100 continues with block 108 in which a solder material layer is formed on the metallization layer. The method 100 continues with block 110 in which the mask layer is removed. The method 100 continues with block 112 in which a wet etching process is performed to remove the uncovered portion of the upper UBM layer. The method 100 continues with block 113 in which an O₂ descum process is performed to oxidize the exposed surfaces of the metallization layer and the lower UBM layer. The method 100 continues with block 114 in which a thermal reflowing process is performed on the solder material layer. The thermal reflow process reshapes the solder material layer to form a solder bump. For example, a hemispherical solder bump. The method 100 continues with block 116 in which a dry etching process is performed to remove a portion of the lower UBM layer using the solder bump as a hard mask. The UBM formation process can mitigate the UBM undercut issue and form the lower UBM layer with a peripheral region extending outside the edge of the solder bump.

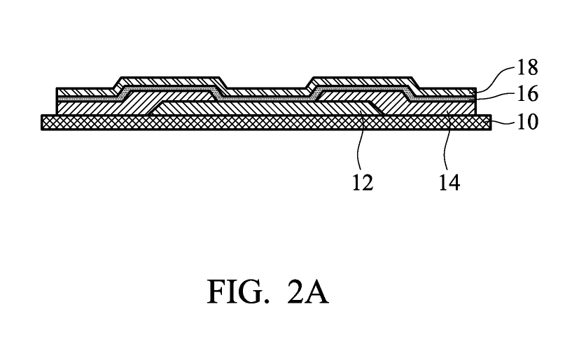

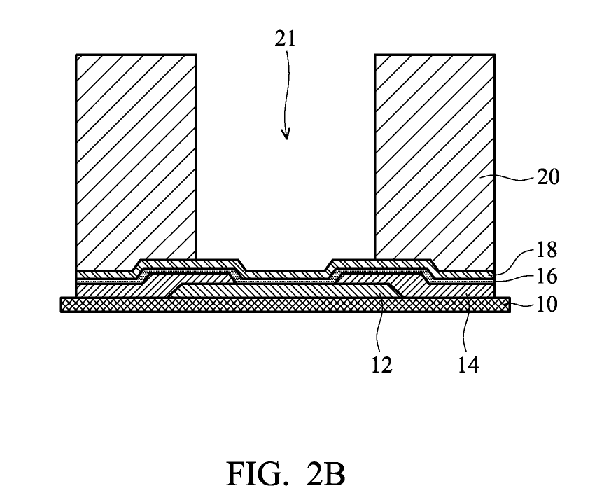

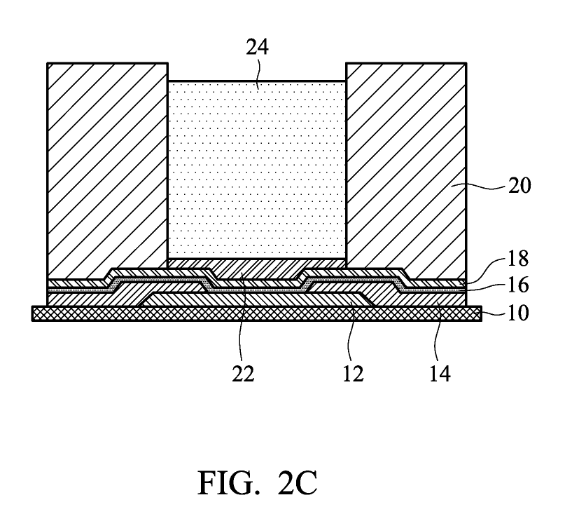

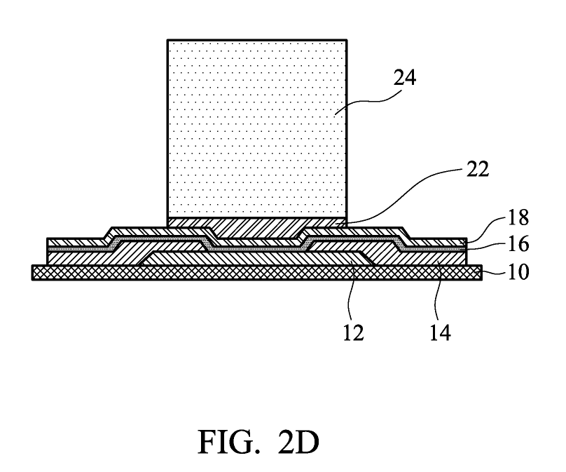

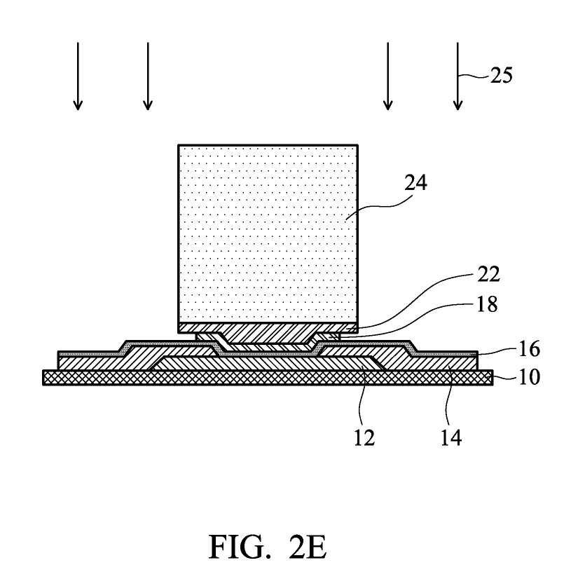

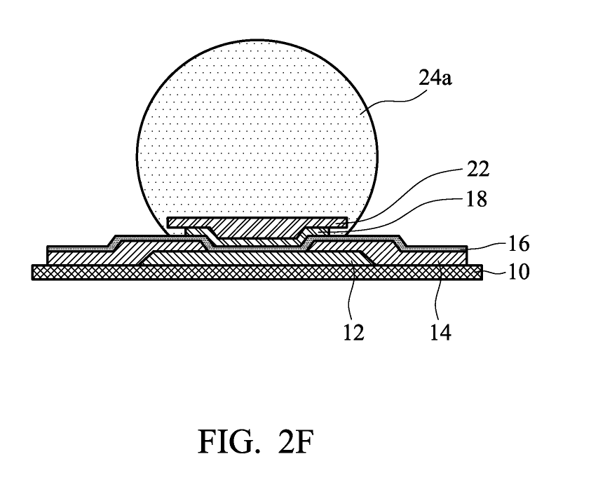

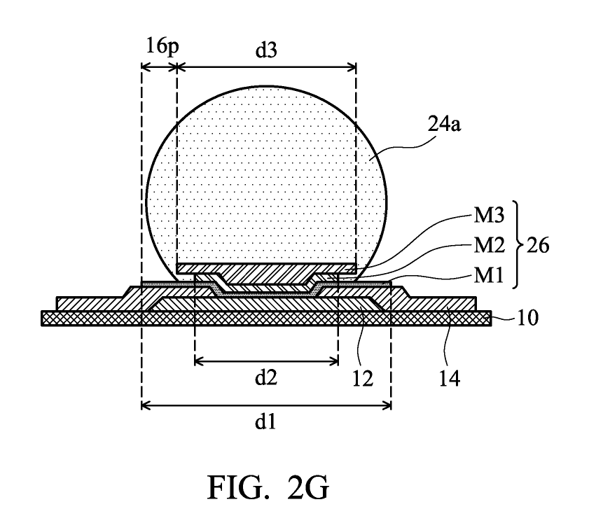

FIGS. 2A˜2G are cross-sectional views of a portion of a semiconductor device at various stages of its fabrication according to the method of FIG. 1

With reference to FIG. 2A, an exemplary semiconductor substrate 10 used for bump fabrication is employed in a semiconductor device fabrication, and integrated circuits may be formed therein and/or thereupon. The semiconductor substrate 10 is defined to mean any construction comprising semiconductor materials, including, but not limited to, bulk silicon, a semiconductor wafer, a silicon-on-insulator (SOI) substrate, or a silicon germanium substrate. Other semiconductor materials including group III, group IV, and/or group V elements may also be used. The substrate 10 may further comprise a plurality of isolation features (not shown), such as shallow trench isolation (STI) features or local oxidation of silicon (LOCOS) features. The isolation features may define and isolate the various microelectronic elements (not shown). Examples of the various microelectronic elements that may be formed in the substrate 10 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; fuses; or other suitable elements. Various processes are performed to form the various microelectronic elements including deposition, etching, implantation, photolithography, annealing, or other suitable processes. The microelectronic elements are interconnected to form the integrated circuit device, such as a logic device, memory device (e.g., static random access memory or SRAM), radio frequency (RF) device, input/output (I/O) device, system-on-chip (SoC) device, combinations thereof, or other suitable types of devices. The semiconductor substrate 10 further includes inter-layer dielectric layers and a metallization structure overlying the integrated circuits. The inter-layer dielectric layers in the metallization structure include low-k dielectric materials, un-doped silicate glass (USG), silicon nitride, silicon oxynitride, or other applicable materials. The dielectric constants (k value) of the low-k dielectric materials may be less than about 3.9, or less than about 2.8. Metal lines in the metallization structure may be formed of copper or copper alloys. One skilled in the art will realize the formation details of the metallization layers.

FIG. 2A depicts a conductive region 12 and a passivation layer 14 formed on the substrate 10. The conductive region 12 is a metallization layer formed over the inter-layer dielectric layers. In some embodiments, the conductive region 12 is a portion of conductive routes and has an exposed surface treated by a planarization process, such as chemical mechanical polishing (CMP). Suitable materials for the conductive region 12 may include, but are not limited to, for example copper, aluminum, copper alloy, or other mobile conductive materials, although it may also be formed of, or include, other materials such as copper, silver, gold, nickel, tungsten, or alloys thereof having a single layer or multi-layer-ed structure. In at least one embodiment, the conductive region 12 is a pad region, a terminal region or an interconnect site of a conductive line, which may be used in the bonding process to connect the integrated circuits in the respective chip to external features. The passivation layer 14 is formed on the substrate 10 and overlying the conductive region 12. Using photolithography and etching processes, the passivation layer 14 is patterned to form an opening exposing a portion of the conductive region 12. In at least one embodiment, the passivation layer 14 is formed of a non-organic material comprising un-doped silicate glass (USG), silicon nitride, silicon oxynitride, silicon oxide, or combinations thereof. In another embodiment, the passivation layer 14 is formed of a polymer layer, such as an epoxy, polyimide, benzocyclobutene (BCB), polybenzoxazole (PBO), or the like, although other relatively soft, often organic, dielectric materials can also be used.

FIG. 2A also depicts the formation of a lower UBM layer 16 and an upper UBM layer 18 on the passivation layer 14. The lower UBM layer 16 and the upper UBM layer 18 are electrically connected to the conductive region 12 through the opening formed in the passivation layer 14. The lower UBM layer 16 is formed on the passivation layer 14 and the exposed portion of the conductive region 12. In at least one embodiment, the lower UBM layer 16 includes a diffusion barrier layer. The diffusion barrier layer, also referred to as a glue layer, is formed to cover the sidewalls and the bottom of the opening of the passivation layer 14. The diffusion barrier layer may be formed of titanium (Ti), although it may also be formed of other materials such as titanium nitride (TiN), titanium oxide (TiOₓ), tantalum (Ta), tantalum nitride (TaN), or combinations thereof, for example, Ti/TiN, Ti/TiN/Ti, or the like. The formation methods include physical vapor deposition (PVD) or sputtering. The upper UBM layer 18 is formed on the lower UBM layer 16. In at least one embodiment, the upper UBM layer 18 is a copper layer formed by performing PVD or sputtering. In some embodiments, the upper UBM layer 18 is formed of copper alloys that include silver, chromium, nickel, tin, gold, or combinations thereof. The lower UBM layer 16 may have a thickness about 1000˜2000 Angstroms, and the upper UBM layer 18 may have a thickness equal to about 3000˜7000 Angstroms, although their thicknesses may also be greater or smaller. The dimensions recited throughout the description are merely examples, and will be scaled with the downscaling of integrated circuits.

Next, as shown in FIG. 2B, a mask layer 20 is provided on the upper UBM layer 18 and patterned with an opening 21 for example, by exposure, development or etching, so that a portion of the upper UBM layer 18 is exposed. In at least one embodiment, the mask layer 20 is a wet photoresist film. In another embodiment, the mask layer 20 is a dry film or an organic material. The thickness of the mask layer 20 may be greater than about 5 micrometers (μm), or even between about 10 μm and about 120 μm.

Next, as shown in FIG. 2C, a metallization layer 22 and a solder material layer 24 are successfully formed in the opening 21 of the mask layer 20. In at least one embodiment, the metallization layer 22 is a nickel layer, a copper layer, or a combination thereof. In some embodiments, the metallization layer 22 is a nickel alloy layer, for example nickel-palladium-gold (NiPdAu), nickel-gold (NiAu), nickel-palladium (NiPd) or other similar alloys. The metallization layer 22 has a thickness less than 10 μm. In some embodiments, the metallization layer 22 has a thickness less than 5 μm, for example about 0.02˜5 μm, although the thickness may be greater or smaller. The metallization layer 22 can be deposited by electroplating, electroless or immersion metal deposition process.

The solder material layer 24 is made of Sn, SnAg, Sn—Pb, SnAgCu, SnAgZn, SnZn, SnBi—In, Sn—In, Sn—Au, SnPb, SnCu, SnZnIn, or SnAgSb, etc by electroplating methods. In at least one embodiment, the solder material layer 24 is a lead-free solder material layer. The solder material layer 24 has a thickness greater than 30 μm. In some embodiments, the solder material layer 24 has a thickness about 40˜100 μm, although the thickness may be greater or smaller. As depicted in FIG. 2C, the solder material layer 24 is electroplated within the opening 21 of the mask layer 20, and the height of the solder material layer 24 does not exceed the height of the mask layer 20. As a result, the solder material layer 24 retains a pillar shape within the opening 21.

Referring to FIG. 2D, the mask layer 20 is then removed from the upper UBM layer 18 followed by etching the uncovered portion of the upper UBM layer 18 as shown in FIG. 2E. In at least one embodiment, a wet etching process is performed with a descum process. For example, a mixture of H₂SO₄ and H₂O₂ are used as an etchant, and the descum process uses O₂. During the wet etching process, the edges of the covered portion of the upper UBM layer 18 located beneath the metallization layer 22 is etched, forming an undercut that extends inwardly no greater than 4 μm. Then a O₂ descum process 25 is performed to oxidize the exposed surfaces of the lower UBM layer 16 and the metallization layer 22 for avoiding solder wetting in subsequent reflowing process.

Referring to FIG. 2F, a thermal reflowing process is performed on the solder material layer 24, forming a hemisphere-shaped solder bump 24a. The solder bump 24a may cover the sidewalls of the metallization layer 22 and the upper UBM layer 18 and the undercut there between. The solder bump 24a, in some embodiments, may be various sizes in diameter and may include so-called “micro-bumps.” For example, the solder bump 24a may be 65-80 μm in diameter. The pitch between solder bumps 24a may be less than 150 μm, such as 130-140 μm, and may in the future get even smaller. For micro-bump applications, the pitch may be 20-50 μm, and the diameter may be 10-25 μm.

Next, as shown in FIG. 2G, using the solder bump 24a as a hard mask, a dry etching process is performed to remove a portion of the lower UBM layer 16. Due to the perimeter of the solder bump 24a, undercutting of the lower UBM layer 16 is avoided. After the dry etching process, the lower UBM layer 16 has a peripheral region 16p extending outside the perimeter of the solder bump 24a. The peripheral region 16p is approximately 4˜10 μm beyond the edge of the metallization layer 22.

This completes a UBM structure 26 underlying the solder bump 24a. The UBM structure 26 includes a first metallization layer M1 with a first cross-sectional dimension d₁ (referring to the lower UBM layer 16), a second metallization layer M2 with a second cross-sectional dimension d₂ (referring to the upper UBM layer 18), and a third metallization layer M3 with a third cross-sectional dimension d₃ (referring to the metallization layer 22). In at least one embodiment, d₁>d₃. In another embodiment, d₃>d₂. In another embodiment, d₁>d₃>d₂. In some embodiments, d₁-d₃>8 μm. In some embodiments, d₃-d₂>4. For example, d₃-d₂=4˜10 μm. The UBM fabrication method uses the hemisphere-shaped solder bump as the hard mask to define the dimension of the lower UBM layer 16. Thus, the UBM undercutting issue is solved, and the UBM dimension can be controllable by well controlling the size of the solder bumps.

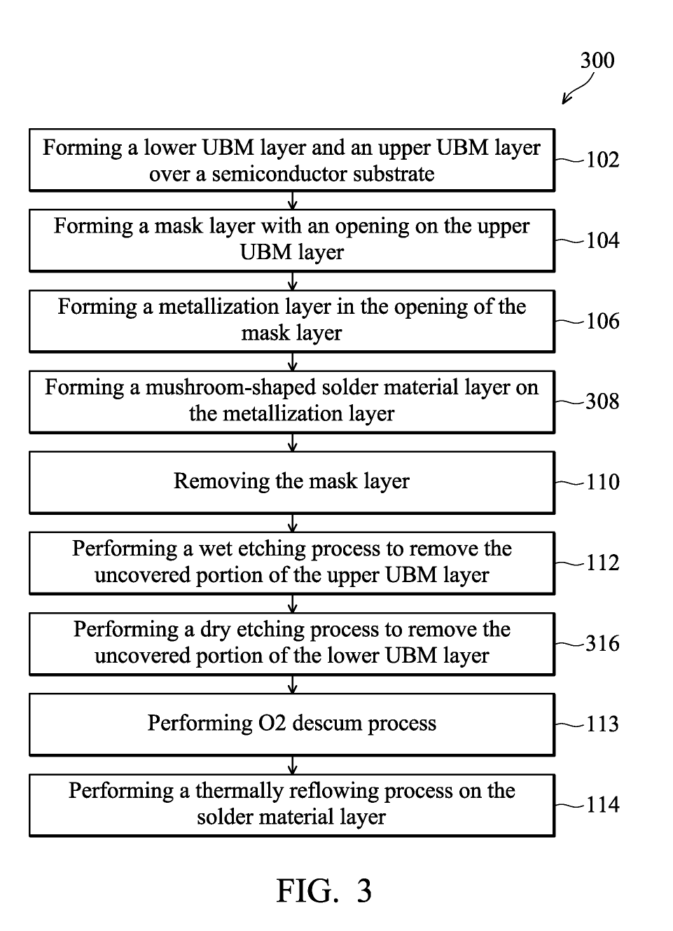

FIG. 3 is a flowchart of another method of fabricating a semiconductor device with a UBM structure according to various aspects of the present disclosure. The explanation of the same or similar portions to the description in FIG. 1 will be omitted.

Referring to FIG. 3, the method 300 begins with block 102 in which a lower UBM layer and an upper UBM layer are formed over a semiconductor substrate. The method 300 continues with block 104 in which a mask layer with an opening is formed on the upper UBM layer. The method 300 continues with block 106 in which a metallization layer is formed in the opening of the mask layer. The method 300 continues with block 308 in which a solder material layer is formed on the metallization layer. The solder material layer is plated to exceed the height of the mask layer to form a mushroom-shaped solder material layer. The method 300 continues with block 110 in which the mask layer is removed. The method 300 continues with block 112 in which a wet etching process is performed to remove the uncovered portion of the upper UBM layer. The method 300 continues with block 316 in which a dry etching process is performed to remove a portion of the lower UBM layer using the mushroom-shaped solder material layer as a hard mask. The method 300 continues with block 113 in which an O₂ descum process is performed to oxidize the exposed surfaces of the metallization layer and the lower UBM layer. The method 300 continues with block 114 in which a thermal reflowing process is performed on the solder material layer. The thermal reflowing process reshapes the solder material layer as a hemispherical solder bump. The UBM formation process can mitigate the UBM undercut issue and form the lower UBM layer with a peripheral region extending outside the edge of the solder bump.

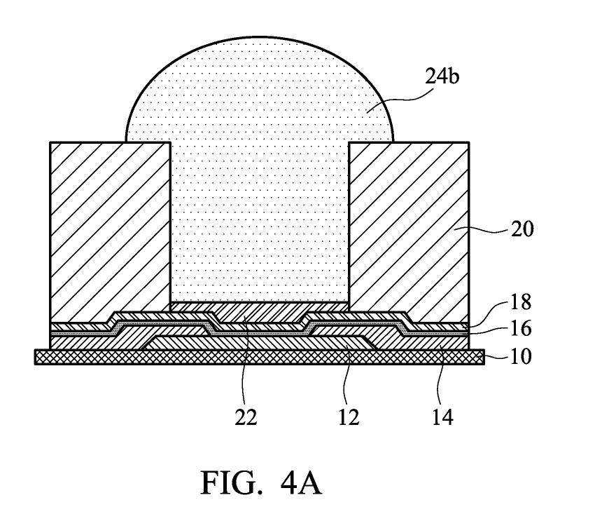

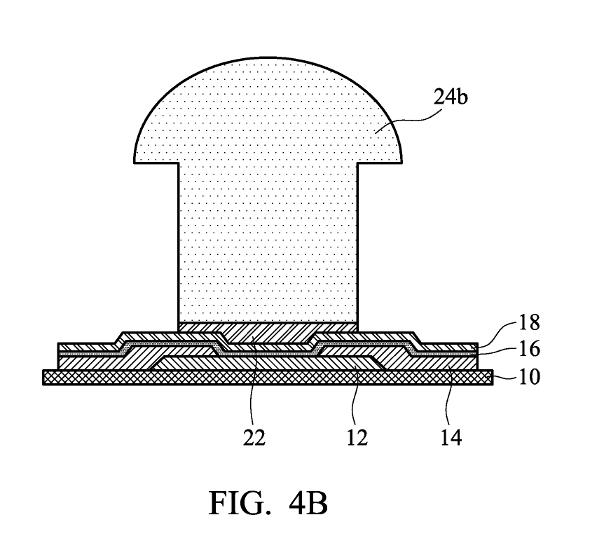

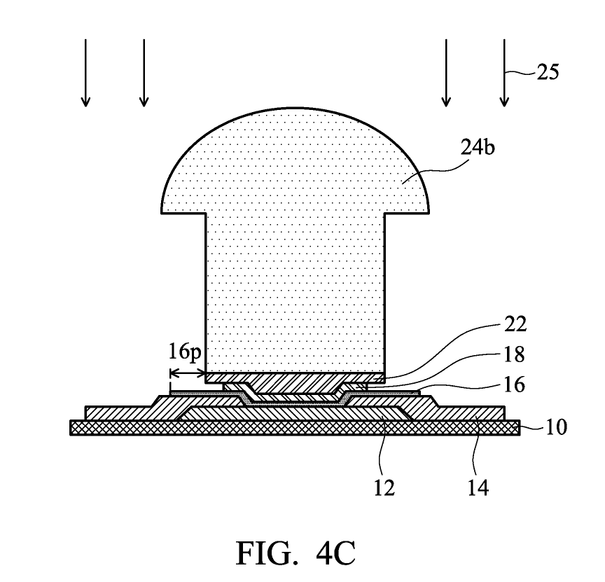

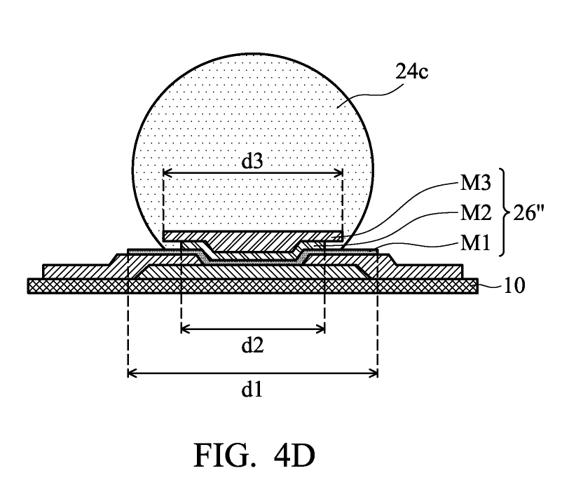

FIGS. 4A˜4D are cross-sectional views of a portion of a semiconductor device at various stages of its fabrication according to an embodiment of the method of FIG. 3. The explanation of the same or similar portions to the description in FIG. 2A to FIG. 2D will be omitted.

Referring to FIG. 4A, after the formation of the metallization layer 22 in the opening of the mask layer 20, the solder material layer is electroplated on the metallization layer 22. The solder plating process can be controlled to form the solder material layer having a height exceeding the height of the mask layer 20 so as to spread out of the opening of the mask layer 20 in a mushroom shape, resulting in a mushroom-shaped solder material layer 24b. As shown in FIG. 4B, the solder mask 20 is then removed. Next, as shown in FIG. 4C, the uncovered portion of the upper UBM layer 18 is removed by a wet etching process, creating an undercut between the metallization layer 22 and the upper UBM layer 18. Then a dry etching process is performed using the mushroom-shaped solder material layer 24b as a hard mask to remove a portion of the lower UBM layer 16. Due to the perimeter of the s mushroom-shaped solder material layer 24b, undercutting of the lower UBM layer 16 is avoided. After the dry etching process, the lower UBM layer 16 has a peripheral region 16p extending outside the edge of the metallization layer 22. The peripheral region 16p is approximately 10˜20 μm beyond the edge of the metallization layer 22. Then a O₂ descum process 25 is performed to oxidize the exposed surfaces of the lower UBM layer 16 and the metallization layer 22 for avoiding solder wetting in subsequent reflowing process. Next, as shown in FIG. 4D, a thermal reflowing process is performed on the solder material layer 24b to form a hemisphere-shaped solder bump 24c.

This completes a UBM structure 26″ underlying the solder bump 24c. The UBM structure 26″ includes a first metallization layer M1 with a first cross-sectional dimension d₁ (referring to the lower UBM layer 16), a second metallization layer M2 with a second cross-sectional dimension d₂ (referring to the upper UBM layer 18), and a third metallization layer M3 with a third cross-sectional dimension d₃ (referring to the metallization layer 22), in which d₁>d₃>d₂. The UBM fabrication method uses the mushroom-shaped solder material layer 24b as the hard mask to define the dimension of the lower UBM layer 16. Thus, the UBM undercutting issue is solved, and the UBM dimension can be controllable by well controlling the size of the solder bumps.

In the preceding detailed description, the disclosure is described with reference to specific exemplary embodiments thereof. It will, however, be evident that various modifications, structures, processes, and changes may be made thereto without departing from the broader spirit and scope of the disclosure. The specification and drawings are, accordingly, to be regarded as illustrative and not restrictive. It is understood that the disclosure is capable of using various other combinations and environments and is capable of changes or modifications within the scope of inventive concepts as expressed herein.

What is claimed is:

1. A semiconductor device, comprising:
a semiconductor substrate;
a under-bump metallization (UBM) structure overlying the semiconductor substrate; and
a solder bump overlying and electrically connected to the UBM structure;
wherein the UBM structure comprises a first metallization layer with a first cross-sectional dimension d₁, a second metallization layer with a second cross-sectional dimension d₂ formed on the first metallization layer, and a third metallization layer with a third cross-sectional dimension d₃ formed on the second metallization layer, in which d₁ is greater than d₃.

2. The semiconductor device of claim 1, wherein d₃ is greater than d₂.

3. The semiconductor device of claim 1, wherein the first metallization layer comprises titanium (Ti).

4. The semiconductor device of claim 1, wherein the second metallization layer comprises copper (Cu).

5. The semiconductor device of claim 1, wherein the third metallization layer comprises at least one of nickel (Ni) and copper (Cu).

6. The semiconductor device of claim 1, wherein the solder bump comprises a lead-free solder material.

7. A method of forming a semiconductor device, comprising:
forming a first metallization layer overlying a semiconductor substrate;
forming a second metallization layer overlying the first metallization layer;
forming a mask layer with an opening overlying second metallization layer;
forming a third metallization layer in the opening of the mask layer;
forming a solder material layer overlying the third metallization layer;
removing the mask layer;
performing a wet etching process to remove an uncovered portion of the second metallization layer;
performing a thermal reflowing process on the solder material layer to form a solder bump; and
performing a dry etching process with the solder bump as a hard mask to remove a portion of the first metallization layer.

8. The method of claim 7, wherein after the wet etching process and the dry etching process, the first metallization layer has a first cross-sectional dimension d₁, the second metallization layer has a second cross-sectional dimension d₂, and the third metallization layer has a third cross-sectional dimension d₃, in which d₁ is greater than d₃.

9. The method of claim 8, wherein d₃ is greater than d₂.

10. The method of claim 7, wherein the first metallization layer comprises at least one of a titanium (Ti) layer, a titanium oxide (TiOₓ) layer, a tantalum (Ta) layer, and a tantalum nitride (TaN) layer.

11. The method of claim 7, wherein the second metallization layer is a copper (Cu) layer.

12. The method of claim 7, wherein the third metallization layer comprises at least one of a nickel (Ni) layer and a copper (Cu) layer.

13. The method of claim 7, further comprising performing a O₂ descum process before the thermal reflowing process.

14. A method of forming a semiconductor device, comprising:
forming a first metallization layer overlying a semiconductor substrate;
forming a second metallization layer overlying the first metallization layer;
forming a mask layer with an opening overlying second metallization layer;
forming a third metallization layer in the opening of the mask layer;
forming a mushroom-shaped solder material layer overlying the third metallization layer;
removing the mask layer;
performing a wet etching process to remove an uncovered portion of the second metallization layer;
performing a dry etching process using the mushroom-shaped solder material layer as a hard mask to remove a portion of the first metallization layer; and
performing a thermal reflowing process on the mushroom-shaped solder material layer to form a solder bump.

15. The method of claim 14, wherein after the wet etching process and the dry etching process, the first metallization layer has a first cross-sectional dimension d₁, the second metallization layer has a second cross-sectional dimension d₂, and the third metallization layer has a third cross-sectional dimension d₃, in which d₁ is greater than d₃.

16. The method of claim 15, wherein d₃ is greater than d₂.

17. The method of claim 14, wherein the first metallization layer comprises at least one of a titanium (Ti) layer, a titanium oxide (TiOₓ) layer, a tantalum (Ta) layer, and a tantalum nitride (TaN) layer.

18. The method of claim 14, wherein the second metallization layer is a copper (Cu) layer.

19. The method of claim 14, wherein the third metallization layer comprises at least one of a nickel (Ni) layer and a copper (Cu) layer.

20. The method of claim 14, further comprising performing a O₂ descum process before the thermal reflowing process.
